(19) United States
(12) Patent Application Publication
(10) Pub. No.: US 2004/0140196 A1
(43) Pub. Date: Jul. 22, 2004

(54) Shaping features in sputter deposition

(75) Inventors: Praburam Gopalraja, San Jose, CA (US); Jianming Fu, Palo Alto, CA (US); Xianmin Tang, San Jose, CA (US); Fusen Chen, Saratoga, CA (US)

Correspondence Address: APPLIED MATERIALS, INC., Patent Department, M/S 2061, P.O. Box 450A, Santa Clara, CA, 95052, US

(73) Assignee: Applied Materials, Inc.

(21) Appl. No.: 10/346,974

(22) Filed: Jan. 17, 2003

(51) Int. Cl. C23C 14/00; C23C 14/32

(52) U.S. Cl. 204/192.12; 204/298.06; 204/298.15; 204/298.08

(57) ABSTRACT

A sputter deposition method is performed in a sputtering chamber having a sputtering target facing a substrate support. A substrate is placed on the support in the chamber and, in a first sputtering stage, a first layer of sputtered material is deposited on the substrate by maintaining a first pressure of a sputtering gas in the chamber, and maintaining the substrate support at a first bias power level. In a second sputtering stage, a second layer of sputtered material is deposited on the substrate by maintaining a second pressure of the sputtering gas that is lower than the first pressure, and maintaining the substrate support at a second bias power level that is higher than the first bias power level.

### BACKGROUND

Embodiments of the present invention relate to the deposition of material on a substrate.

In the manufacture of electronic circuits, such as for example, integrated circuits and displays, a substrate is processed by depositing material on the substrate and etching the material to form the features. The material may be deposited by a physical vapor deposition (PVD) process, such as sputter deposition, in which, a sputtering target comprising material to be deposited on the substrate is positioned facing the substrate in a sputtering chamber. An energized sputtering gas bombards the sputtering target with energetic ions causing material to be knocked off the target and deposited on the substrate. The sputtered material may also chemically react with components of the sputtering gas in depositing on the substrate. The sputtered material deposited on the substrate may comprise a metal such as for example, aluminum, copper, tungsten or tantalum; or a metal compound such as tantalum nitride, tungsten nitride or titanium nitride.

A sputter deposition process can be used to form electrical interconnect features, such as wiring lines and contact plugs, that are used to electrically connect other features on the substrate. Referring to FIGS. 1a and 1b, one method of forming such an interconnect feature uses a substrate 10 comprising a dielectric layer 12 that is formed over a copper layer 14, and which has an etched feature 16 therein. A barrier layer 18 lines the sidewalls 20 and bottom wall 22 of the feature 16 to inhibit diffusion of copper that is subsequently deposited over the dielectric layer 12. A copper sputter deposition process is performed to deposit copper layers 24 into the etched feature 16 to cover the barrier layer 18, as shown in FIG. 1b. The copper layers 24 can serve as a seed layer for the electroplating of copper material in the feature 16 to fill the feature 16 to form a contact plug.

However, one problem with such a method is that the portion of the barrier layer 18 that remains between the copper layers 14, 24 has a small but finite transverse resistance which yields an undesirably high contact-resistance between the upper and lower copper layers 14, 24. U.S. Pat. No. 5,985,762 to Geffken et al., which is incorporated herein by reference in its entirety, discloses a separate etching step to remove a portion of the barrier layer 18 to reduce the contact-resistance. However, the etching method typically requires transferring of the substrate from the sputter deposition chamber to a separate etching chamber, thereby undesirably increasing the time required to process the substrate and also increasing the possibility of substrate contamination during the transport step. Etching processes also use etchant gases that may undesirably corrode or otherwise damage the metal features formed on the substrate.

A partial solution to this problem comprises depositing copper layers 24 in a series of steps while etching away portions of the barrier layer 18, as shown in FIGS. 1c to 1d, and described in U.S. Pat. No. 6,451,177, entitled “A Vault Shaped Target and Magnetron Operable in Two Sputtering Modes,” to Gopalraja et al, assigned to Applied Materials, which is also incorporated herein by reference in its entirety. In a first step, energetic copper ions anisotropically bombard the substrate 10 to sputter away the barrier layer 18 at the bottom of the feature 16 while. simultaneously depositing a first copper layer 24a on the sidewalls 20 of the feature 16, as shown in FIG. 1c. Once the lower portion of the barrier layer 18 has been removed in the first sputtering step, a second sputter deposition step is performed to deposit a second copper layer 24b over the exposed portion of the underlying copper layer 14 and on the feature sidewalls 20 by providing a plasma having lower energy ions and a greater fraction of neutral sputtering material species. Thus, this method removes the portion of the barrier layer 18 separating the over and underlying copper layers 14, 24, and provides for reduced resistance at the interface between the under and overlying layers 14, 24.

However, such sputtering methods are difficult to use to sputter deposit material into features 16 having sloped sidewalls. These sloped sidewalls may be formed, for example, as a result of an anisotropic or other etching process used to form the feature 16 in the substrate 10. For example, during etching of the feature 16 in the substrate 10, the upper and lower portions of the feature sidewalls 20 may be etched at different rates due to better access of energized etchant gas species to the upper portions of the feature sidewalls. The upper portions of the feature sidewalls etch at a faster rate than the lower sidewall portions, resulting in a feature having sloped sidewalls that provide a wider feature opening at the surface of the substrate 10 that narrows with increasing feature depth. When sloped sidewalls are present, the first high energy sputter deposition step to remove the bottom portion of the barrier layer 18 also undesirably sputters material from the barrier layer 18 covering the sidewalls 20. This occurs because the sloped sidewalls 20 provide angled surfaces that receive oncoming energetic ions and allow the ions to energetically sputter away material from the sidewalls 20. The sputtering away of barrier layer material from the sidewalls 20 is undesirable because the sputtered barrier material re-deposits at the bottom of the feature 16 and increases the resistance of the copper interconnect.

Thus, it is desirable to form interconnect features having good electrical properties and low resistances. It is also desirable to sputter deposit material in the fabrication of electrical interconnects without leaving behind high contact resistant regions. It is further desirable to sputter depositing material into features having sloped sidewalls to form electrical interconnects without damaging existing layers on the sidewalls.

### SUMMARY

In one embodiment, a sputter deposition method is performed in a sputtering chamber having a sputtering target facing a substrate support. The method comprises placing a substrate on the support in the chamber and performing first and second sputtering stages. In a first sputtering stage, a first layer of sputtered material is deposited on the substrate by maintaining a first pressure of a sputtering gas in the chamber, and maintaining the substrate support at a first bias power level. In a second sputtering stage, a second layer of sputtered material is deposited on the substrate by maintaining a second pressure of the sputtering gas that is lower than the first pressure, and maintaining the substrate support at a second bias power level that is higher than the first bias power level.

In another embodiment of a sputter deposition method performed in a is sputtering chamber having a sputtering target facing a substrate support, the method comprises placing a substrate on a support in the chamber, the substrate comprising a first layer overlying a second layer, where the first layer comprises a feature having a bottom wall and sloped sidewalls. In a first sputtering stage, first sputtering process conditions are maintained to deposit sputtered material on the sloped sidewalls of the feature, thereby protecting the sloped sidewalls. The first sputtering process conditions comprise maintaining a pressure of a sputtering gas in the chamber of from about 3 mTorr to about 10 mTorr, and maintaining the substrate support at a first bias power level of from about 0 Watts to about 200 Watts. In a second sputtering stage, second sputtering process conditions are maintained to sputter the bottom wall of the feature to expose a portion of the second layer. The second sputtering process conditions comprises maintaining a pressure of the sputtering gas in the chamber of from about 0 mTorr to about 2 mTorr, and maintaining the substrate support at a second bias power level that is higher than the first bias power level, the second bias power level being from about 200 Watts to about 800 Watts.

In yet another embodiment, a sputter deposition method performed in a sputtering chamber having a sputtering target comprising copper facing a substrate support comprises placing a substrate on the support in the chamber, the substrate comprising a barrier layer over an underlying layer of copper, wherein the barrier layer comprises a feature formed therein, the feature having a bottom wall and sloped sidewalls. In a first sputtering stage, first sputtering process conditions are maintained to deposit copper sputtered from the target onto the sloped sidewalls of the feature, thereby protecting the sloped sidewalls. The first sputtering process conditions comprise maintaining a pressure of a sputtering gas comprising Ar in the chamber of from about 3 mTorr to about 10 mTorr, and maintaining the substrate support at a first bias power level of from about 0 Watts to about 200 Watts. In a second sputtering stage, second sputtering process conditions are maintained to sputter the bottom wall of the feature to expose a portion of the underlying copper layer. The second sputtering process conditions comprise maintaining a pressure of the sputtering gas in the chamber of from about 0 mTorr to about 2 mTorr, and maintaining the substrate support at a second bias power level that is higher than the first bias power level, the second bias power level being from about 200 Watts to about 800 Watts. In a third sputtering stage, third sputtering process conditions are maintained to deposit copper sputtered from the target onto the sidewalls of the feature and onto the exposed portion of the underlying copper layer. The third sputtering process conditions comprise maintaining a pressure of the sputtering gas in the chamber of from about 3 mTorr to about 10 mTorr, and maintaining the substrate support at a third bias power that is less than the second bias power level, the third bias power level being from about 0 Watts to about 200 Watts.

One embodiment of a sputtering chamber for sputter depositing material on a substrate comprises a substrate support, a target facing the substrate support, a sputtering gas delivery system to provide a sputtering gas in the chamber, a gas energizer to energize the sputtering gas by applying bias power levels to the target and the substrate support, thereby sputtering material from the target onto the substrate, an exhaust comprising a throttle valve to control a pressure of the sputtering gas in the chamber, and a controller comprising a computer having computer readable program code embodied in a computer readable medium. The computer readable program code comprises gas energizer control instruction sets to operate the gas energizer to, during a first sputtering stage, apply a first bias power level to the support, and during a second sputtering stage performed after the first sputtering stage, apply a second bias power level to the support that is higher than the first bias power level. The computer readable program further comprises gas pressure control instruction sets to operate the throttle valve to, during the first sputtering stage, maintain a first pressure of sputtering gas in the chamber, and during the second sputtering stage, maintain a second pressure of the sputtering gas that is lower than the first pressure.

### DRAWINGS

These features, aspects, and advantages of the present invention will become better understood with regard to the following description, appended claims, and accompanying drawings which illustrate examples of the invention. However, it is to be understood that each of the features can be used in the invention in general, not merely in the context of the particular drawings, and the invention includes any combination of these features, where:

FIG. 1a (Prior Art) is a schematic cross-sectional view of a substrate comprising a dielectric layer overlying conducting layer, the dielectric layer having a feature formed therein that is lined with a barrier layer;

FIG. 1b (Prior Art) is a schematic cross-sectional view of the substrate of FIG. 1a after a deposition stage has been performed to deposit a layer of material over the barrier layer;

FIG. 1c (Prior Art) is a schematic cross-sectional view of the substrate of FIG. 1a after a first deposition stage has been performed to sputter away a bottom portion of the barrier layer and deposit a first layer of material on sidewalls of the feature;

FIG. 1d (Prior Art) is a schematic cross-sectional view of the substrate of FIG. 1c after a second deposition stage has been performed to deposit a second layer of material in the feature;

FIG. 2 is a schematic top view of a multi-chamber processing apparatus according to an embodiment of the present invention;

FIG. 3a is a partial sectional schematic side view of a version of a sputtering chamber according an embodiment of the present invention;

FIG. 3b is a partial sectional schematic side view of another embodiment of a magnetron suitable for the chamber of FIG. 3a;

FIG. 4a is a schematic cross-sectional view of a substrate comprising a dielectric layer overlying conducting layer, the dielectric layer having a feature comprising sloped sidewalls formed therein and the feature being lined with a barrier layer;

FIG. 4b is a schematic cross-sectional view of the substrate of FIG. 4a after a first deposition stage has been performed to deposit a first layer of material in the feature;

FIG. 4c is a schematic cross-sectional view of the substrate of FIG. 4b after a second deposition stage has been performed to sputter away a bottom portion of the barrier layer and to deposit a second layer of material over the sloped sidewalls;

FIG. 4d is a schematic cross-sectional view of the substrate of FIG. 4c after a third deposition stage has been performed to deposit a third layer of material in the feature;

FIG. 5 is a flow chart illustrating an embodiment of a method of sputter depositing material on a substrate;

FIG. 6a is an illustrative block diagram of a version of a controller suitable to control the chamber of FIG. 3a; and

FIG. 6b is an illustrative block diagram of a version of a computer readable program for the controller of FIG. 6a.

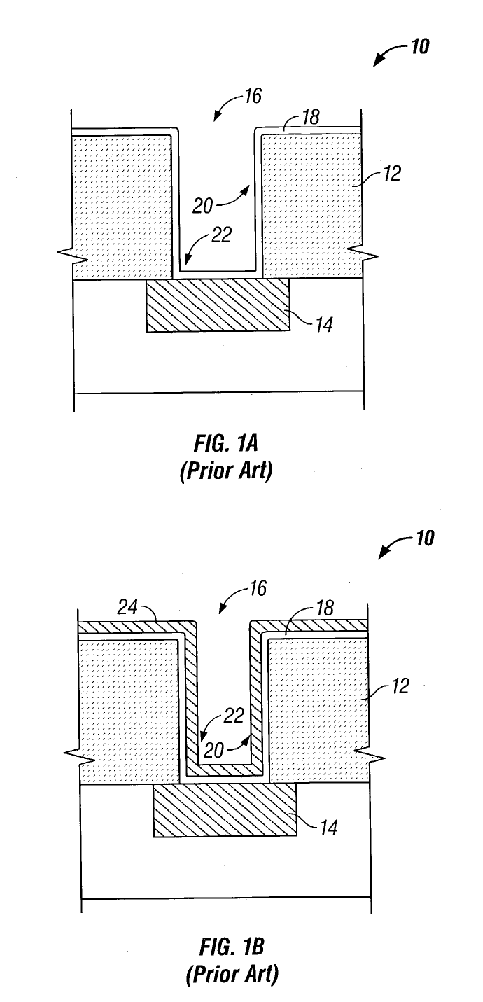

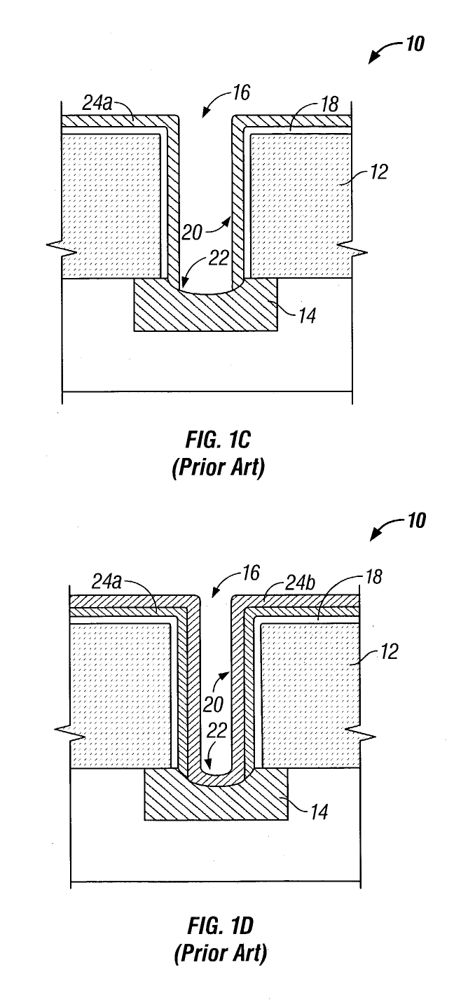

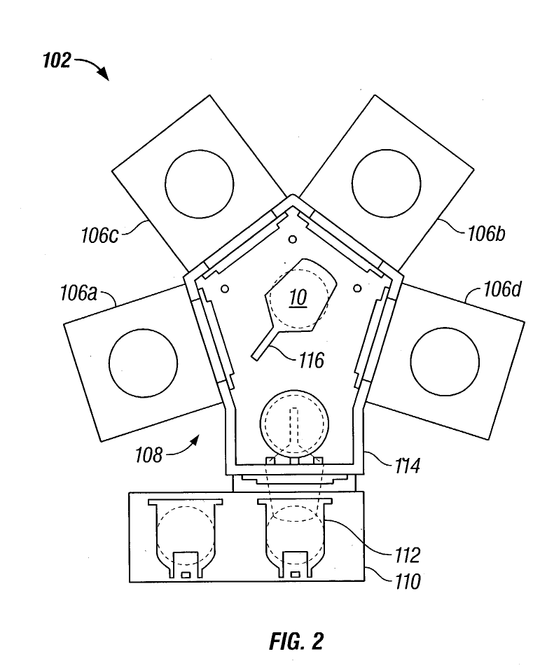

### DESCRIPTION

An embodiment of an apparatus 102 suitable for processing substrates 10 comprises one or more process chambers 106a-d, as shown in FIG. 2. The chambers 106a-d are mounted on a platform, such as an Endura platform from Applied Materials, Inc., of Santa Clara, Calif. that provides electrical, plumbing, and other support functions. The platform 108 typically supports a load lock 110 to receive a cassette 112 of substrates 10 to be processed and a substrate transfer chamber 114 containing a robot 116 to transfer substrates from the cassette 112 to the different chambers 106a-d for processing and return them after processing. The different chambers 106a-d may include, for example, a deposition chamber for depositing materials on substrates, an etching chamber for etching substrates, a resist stripping chamber for removing residue remaining on substrates, annealing chambers, and oxidation or nitridation chambers. The chambers 106a-d are interconnected in a vacuum environment so that the process may proceed uninterrupted within the apparatus 102, thereby reducing contamination of substrates 10 that may otherwise occur when transferring substrates between separate chambers for different process stages. The particular embodiment of the apparatus 102 shown herein is suitable for processing substrates 10 such as semiconductor .wafers, and may be adapted by those of ordinary skill to process other substrates 10, such as flat panel displays, polymer panels, or other electrical circuit receiving structures; thus, the apparatus 102 should not be used to limit the scope of the invention or its equivalents to the exemplary embodiments provided herein.

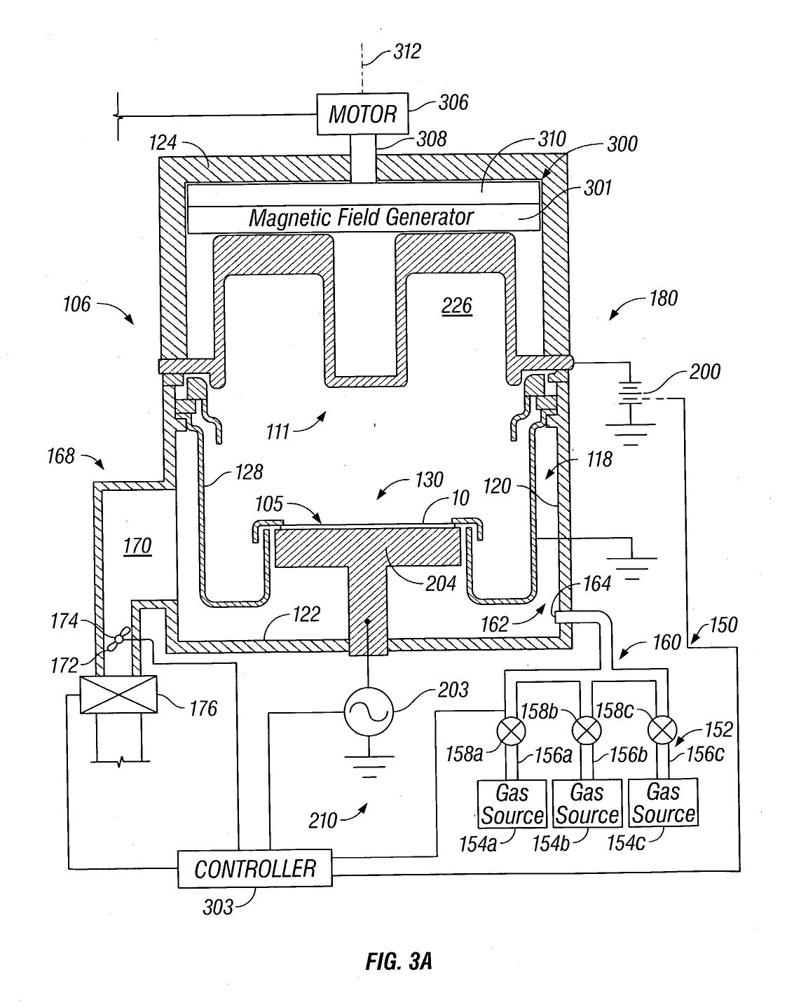

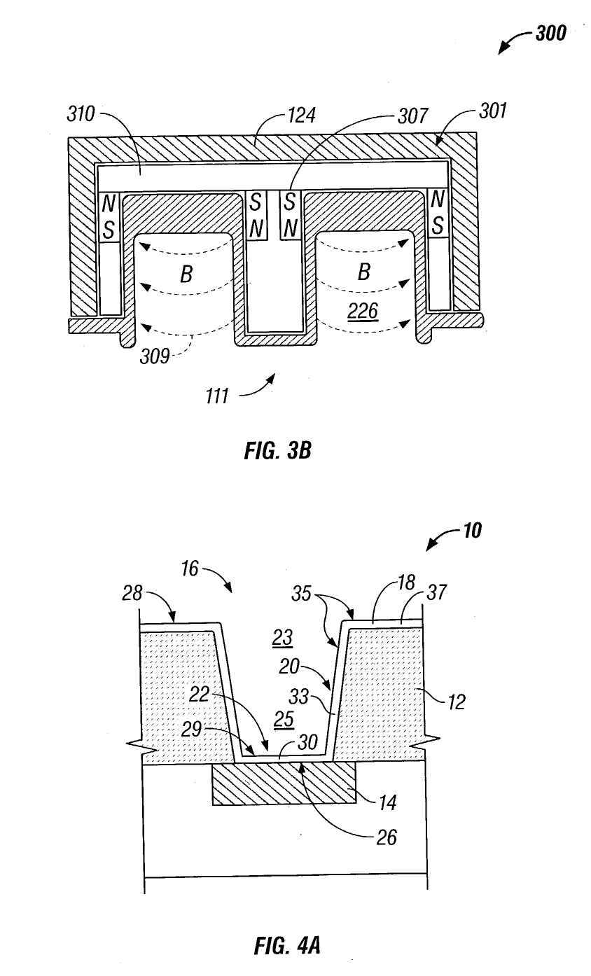

An exemplary version of a chamber 106 capable of sputter depositing material on a substrate 10 is schematically illustrated in FIG. 3a. The chamber 106 is representative of a self-ionized plasma chamber, or SIP+ chamber, from Applied Materials, Inc. of Santa Clara, Calif. A typical chamber 106 comprises enclosure walls 118 that include sidewalls, 120, a bottom wall 122 and a ceiling 124. The chamber 106 can have a process volume of at least about 1997.95 in³, and often a volume of from about 1997.95 in³ to about 4573.18 in³ for processing 200 to 300 nm silicon wafer substrates, or equivalent volumes for smaller or larger substrates.

The chamber 106 further comprises a substrate support 130 to support a substrate 10 in the sputter deposition chamber 106. The substrate support 130 may be electrically floating or may comprise an electrode 204 that is biased by a support power supply 210, which may be for example an RF power supply 203. The electrode power supply 210 may also bias the support electrode 204 by applying an RF bias from the RF power supply 203 through an isolation capacitor, which results in a controlled negative DC self-bias. The substrate 10 is introduced into the chamber 106 through a substrate loading inlet (not shown) in a sidewall 120 of the chamber 106 and placed on the support 130. The support 130 can be lifted or lowered by support lift bellows (not shown) and a lift finger assembly (also not shown) can be used to lift and lower the substrate 10 onto the support 130 during transport of the substrate 10 into and out of 10 the chamber 106.

A process gas, such as a sputtering gas, is introduced into the chamber 106 through a gas delivery system 150 that includes a process gas supply 152 comprising gas sources 154a-c that each feed a conduit 156a-c having a gas flow control valve 158a-c, such as a mass flow controller, to pass a set flow rate of the gas therethrough. The conduits 156a-c feed the gases to a mixing manifold 160 in which the gases are mixed to from a desired process gas composition. The mixing manifold 160 feeds a gas distributor 162 having one or more gas outlets 164 in the chamber 106. The gas outlets 164 may pass through the chamber sidewalls 120 to terminate about a periphery of the substrate support 130. The process gas may comprise a non-reactive gas, such as argon or xenon, that is capable of energetically impinging upon and sputtering material from a target 111. The process gas may also comprise a reactive gas, such as one or more of an oxygen-containing gas and a nitrogen-containing gas, that are capable of reacting with the sputtered material to form a layer on the substrate 10. Spent process gas and byproducts are exhausted from the chamber 106 through an exhaust system 168 which includes one or more exhaust ports 170 that receive spent process gas and pass the spent gas to an exhaust conduit 172 in which there is a throttle valve 174 to control the pressure of the gas in the chamber 106. The exhaust conduit 172 feeds one or more exhaust pumps 176. Typically, the pressure of the sputtering gas in the chamber 106 is set to sub-atmospheric levels.

The sputtering chamber 106 further comprises a sputtering target 111 facing a surface 105 of the substrate 10. The target 111 may comprise a planar target 111 (not shown) or a non-planar target 111 (as shown). The sputtering chamber 106 may also have a shield 128 to protect a wall 118 of the chamber 106 from sputtered material, and typically, to also serve as an anode with respect to the cathode target 111. The shield 128 may be electrically floating or grounded. The target 111 is electrically isolated from the chamber 106 and is connected to a target power supply 200, such as a pulsed DC power source, but which may also be other types of voltage sources. In one version, the target power supply 200, target 111, shield 128, operate as a gas energizer 180 that is capable of energizing the sputtering gas to sputter material from the target 111. The target power supply 200 applies a bias voltage to the target 111 relative to the shield 128. The electric field generated in the chamber 106 from the voltage applied to the sputtering target 111 energizes the sputtering gas to form a plasma that energetically impinges upon and bombards the target 111 to sputter material off the target 111 and onto the substrate 10. The support 130 having the electrode 204 and support electrode power supply 210 may also operate as part of the gas energizer 180 by energizing and accelerating ionized material sputtered from the target 111 towards the substrate 10. In one version, a suitable pulsing frequency of a pulsed DC voltage for energizing the sputtering gas may be, for example, at least about 50 kHz, and more preferably less than about 300 kHz, and most preferably about 100 kHz. A suitable DC voltage level to energize the process gas may be, for example, from about 200 to about 800 Volts.

The chamber 106 further comprises a magnetron 300 comprising a magnetic field generator 301 that generates a magnetic field near the target 111 of the chamber 106 to increase an ion density in a high-density plasma region 226 adjacent to the target 111 to improve the sputtering of the target material, as shown in FIGS. 3a and 3b. An improved magnetron 300 may be used to allow sustained self-sputtering of copper or sputtering of aluminum, titanium, or other metals; while minimizing the need for non-reactive gases for target bombardment purposes, as for example, described in U.S. Pat. No. 6,183,614 to Fu, entitled “A Rotating Sputter Magnetron Assembly”; and U.S. Pat. No. 6,274,008 to Gopalraja et al., entitled “An Integrated Process for Copper Via Filling”, both of which are incorporated herein by reference in their entirety. The magnetic field extends through the substantially non-magnetic target 111 into the sputtering chamber 106. In one version, the magnetic field generator 301 comprises magnets 307 that extend along one or more sidewalls of the target 111 and are connected by a magnetic yoke 310, as shown in FIG. 3b. The magnets 307 may comprise one or more of an inner magnet and outer magnet that are connected together by a yoke 310 that is formed of a magnetically soft material. The magnetic field generator 301 comprising the magnets 307 provides an enhanced magnetic field 309 in the region 226 enclosed by the target sidewalls, thereby increasing the density of the plasma in the region 226. In another version, the magnetron 300 comprises a motor 306 to rotate the magnetron 300 about a rotation axis 312, as shown in FIG. 3a. The motor 306 is typically attached to the magnetic yoke 310 of the magnetron 300 by a shaft 308 that extends along the rotation axis 312.

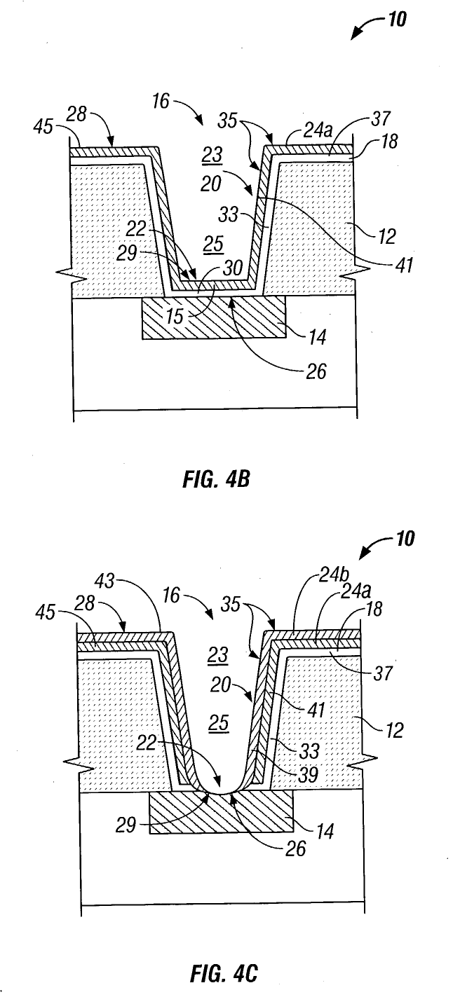

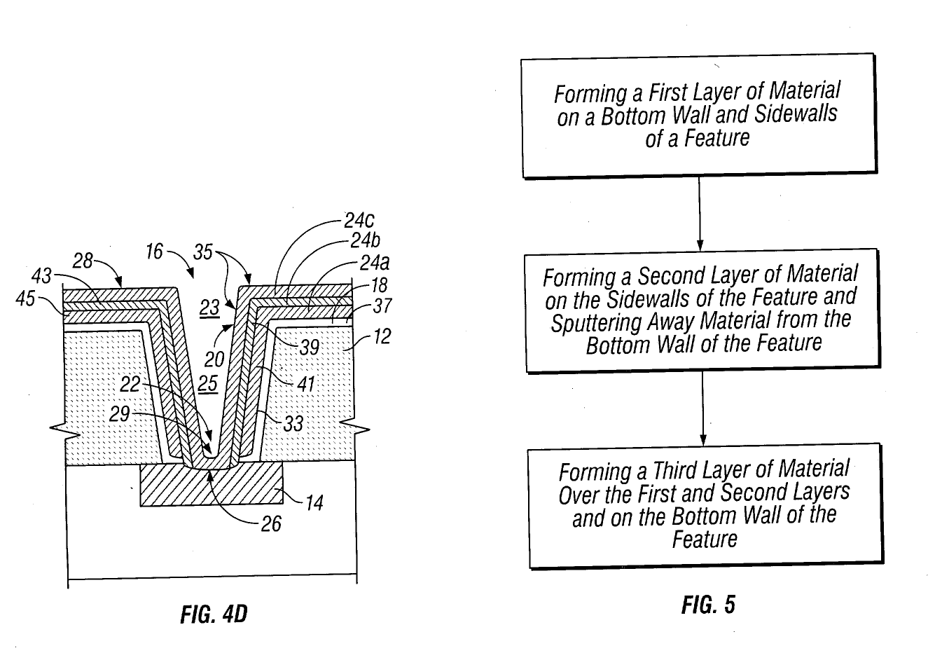

A sputtering process is performed in the chamber 106 to deposit sputtered material in features 16 on a substrate 10. In the version shown in FIG. 4a, the substrate 10 comprises an underlying conducting layer 14 having a dielectric layer 12 formed thereover. The conducting layer 14 comprises a metal material, such as for example, one or more of copper, aluminum, titanium and tantalum. The dielectric layer 12 comprises a less conducting or insulating layer, and may comprise, for example, at least one of silicon oxide, fluorosilicate glass and a low k dielectric. A feature 16 is formed in the dielectric layer 12, the feature comprising sidewalls 20 and a bottom wall 22. In one version, the feature 16 comprises straight sidewalls (not shown) that are perpendicular to an upper surface 28 of the substrate 10. The feature 16 may also comprise sloped sidewalls 20 (shown), such as for example sidewalls 20 that are sloped to form an angle with the upper surface 28 of the substrate 10 of less than 90°, such as for example from about 80° to about 89°. The feature 16 may comprise a desired height or length in the substrate 10, for example feature 16 may comprise a length that extends to an upper surface 26 of the underlying conducting layer 14. A barrier layer 18 is formed over the sidewalls 20 and bottom wall 20 of the feature 16 to protect the dielectric layer 12. A suitable barrier layer 18 may comprise, for example, at least one of tantalum, tantalum nitride, tungsten, tungsten nitride, titanium and titanium nitride.

In the sputter deposition process, the sputtering gas is energized in the sputtering chamber 106 to sputter material from the target 111 onto the substrate 10 to form one or more layers of sputtered material in the features 16. The material sputtered from the target 111 may deposit directly on the substrate 10 to form the layers. The sputtered material may also chemically react with components of the sputtering gas, such as for example a nitrogen gas component, to form compounds that deposit on the substrate 10 to form layers on the substrate 10. A target 111 suitable for depositing one or more layers of material on the substrate 10 comprises, for example, at least one of copper, aluminum, tantalum and titanium. The layers formed on the substrate 10 by sputtering of the target 111 can comprise, for example, at least one of copper, aluminum, tantalum, tantalum nitride, titanium and titanium nitride.

An exemplary method of sputter depositing the material on the substrate comprises a multistage deposition process, as illustrated in the flow chart of FIG. 5. In this version, the sputtering process comprises a first sputtering stage to form a first layer 24a of sputtered material on the bottom wall 22 and sidewalls 20 of the feature 16, thereby protecting the feature sidewalls 20. A second stage performed after the first stage forms a second layer 24b of sputtered material on the sidewalls 20 while sputtering away material from the bottom wall 22 of the feature 16, thereby removing a bottom portion 15 of the first layer 24a and a bottom portion 30 of the barrier layer 18. A third sputtering stage may then be performed to deposit a third layer 24c of sputtered material over the first and second layers 24a,b and the bottom wall 22.

The desired deposition of the layers 24a,b,c and the removal of the bottom portion 30 of the barrier layer 18 is provided by selecting process conditions to provide the desired deposition rates and distribution during each stage of the multistage process. It has been discovered that the rate and distribution of the deposition of material on the substrate 10 are affected by the ionization fraction of the material sputtered from the target 111 and the energy of the ionized sputtered material. The ionization fraction of the sputtered material is a measure of the extent to which the material sputtered from the target 111 has become ionized. A higher ionization fraction means a greater number of ionized and charged sputtered species are formed by sputtering of the target 111, whereas a lower ionization fraction means fewer ionized species and more neutral sputtered species are formed. The gaseous ionized and neutral sputtered species interact differently with the substrate 10 to provide the different deposition rates. For example, the neutral species may deposit on the substrate 10 to form layers of deposited material, while the ionized species may energetically bombard the substrate 10 and even sputter material away from the substrate 10. For example, the ionized species may energetically impinge upon surfaces 35 of the substrate 10 that are angled to at least partially face the direction from which the ionized species are accelerated, such as surfaces 35 that at least partially face the target 111, thereby sputtering material away from these surfaces 35. Increasing the energy of the ionized species, for example by coupling electromagnetic energy to the ionized species, provides a more energetic bombardment of the substrate 10, and thus increases the rate at which material is sputtered away from the substrate 10. Thus, the relative deposition rates and the distribution of the sputtered material on the substrate 10 can be provided by selecting process conditions that provide for the desired ionization fraction and ion energy.

Furthermore, the deposition rate and distribution is also affected by the shape and geometry of the feature 16 on the substrate 10. For example, neutral sputtered species may tend to deposit on more easily accessible regions of the substrate 10, such as the upper surface 28 of the substrate 10 and in the upper region 23 of the feature 16, but these neutral species may be more shielded from the lower region 25 of the feature 16. Energetic ionized species on the other hand may be drawn towards the lower region 25 and bottom wall 22 of the feature 16, for example by applying a bias power level to the substrate support 130 having the electrode 204 beneath the substrate 10 to couple energy to the ionized species and accelerate them towards the substrate 10. The energetic ionized species energetically impinges on exposed surfaces 35 of the substrate 10, such as the surface 29 of the bottom wall 22, the upper surface 28 of the substrate 10, and surfaces of sloped sidewalls 20, thereby sputtering material away from these surfaces 35. Accordingly, by selecting process conditions to provide a desired ionization fraction and ion energy of the material sputtered from the target 111, the desired rate and distribution of deposition of the sputtered material may be controlled to provide for the deposition of the layers 24a,b,c in the feature 16 and the removal of the bottom portion 30 of the barrier layer 18 in the multistage sputter deposition process.

Process conditions that affect the ionization fraction and ion energy of gaseous sputtering material species include the pressure of the sputtering gas in the chamber and bias power level applied to the substrate support 130. A bias power level applied to the support 130 increases the ionization fraction of the material sputtered from the target 111 and increases the energy of the ionized sputtering material by accelerating the charged ionized species towards the substrate 10, thereby increasing the force with which the ionized species impact the substrate 10. Thus, a higher bias power level applied to the support 130 results in a higher rate of sputtering of material from surfaces 35 such as the bottom surface 29 of the feature 16. A lower support bias power level on the other hand results in a smaller ionization fraction and a lower ion energy, thus reducing the rate of sputtering of material from the substrate surfaces 35. The pressure of the sputtering gas in the chamber 106 also affects the ionization fraction energy of the ionized sputtering material species and affects the self-bias of the support 130. For higher pressures, a lower (less negative) self bias develops on the support 130, thereby decreasing the acceleration of the ionized species towards the substrate 10, whereas for lower pressures, a higher (more negative) self bias develops, thereby increasing the ion energy. Thus, the chamber pressure and support bias power level may be selected to provide a desired ionization fraction and energy of ionized sputtering material species to provide the desired deposition rate and distribution in each sputtering stage. Other process conditions that may be selected to provide the desired deposition include, for example, the bias power level applied to the target 111, and the strength and distribution of the magnetic field generated by the magnetron 300.

In the first sputter deposition stage, process conditions are selected to deposit the first layer 24a of sputtered material on the surfaces 35 of the sidewalls 20 and bottom wall 22 of the feature 16, as well as on the upper surface 28 of the substrate 10, as shown in FIG. 4b. The first layer 24a forms a conformal layer covering the surfaces 35 of the bottom portion 30, side portions 33 and top portion 37 of the barrier layer 18. To deposit the first layer 24a, the process conditions are selected to provide relatively fewer highly energized ionized sputtered material species to reduce any sputtering away of material from the substrate 10 and to increase the rate at which material is deposited on the substrate 10.

The process conditions selected to deposit the first layer 24a comprise at least one of the bias power level applied to the support 130 and the pressure of the sputtering gas in the chamber 106. In one version, the process conditions are selected to deposit the first layer 24a of sputtered material on the substrate 10 by selecting a relatively low bias power level applied to the support 130, such as for example, a bias power level less than about 200 Watts, such as from about 0 Watts to about 200 Watts, and even a bias power level less than about 180 Watts, such as from about 0 Watts to about 150 Watts. The process conditions may also be provided by selecting a relatively high chamber pressure, such as a pressure of at least about 3 mTorr, such as from about 3 mTorr to about 10 mTorr, and even from about 4 mTorr to about 10 mTorr. The relatively low bias power and relatively high pressure provides relatively fewer energized ionized species, thereby allowing for the growth of the first layer 24a on surfaces of the substrate 10.

After the first layer 24a of sputtered material is deposited, a second sputtering process stage is performed to sputter away material from the bottom wall 22 of the feature and form a second layer 24b. In one version, the second sputtering stage is performed to sputter away a bottom portion 15 of the first layer 24a and the bottom portion 30 of the barrier layer 18, and to deposit a second layer 24b of sputtered material over the first layer 24a on the sidewalls 20 of the feature 16, as shown in FIG. 4c. To perform the second stage, the process conditions are selected in the second sputtering stage to provide a relatively higher number of energized sputtered ions to energetically bombard the substrate 10 and sputter away material is from surfaces 35 facing the direction of ion bombardment, such as the surface 35 of the bottom wall 22. While the upper surface 28 of the substrate 10 is also bombarded by the energetic ions, the rate of deposition of neutral sputtered species is sufficiently high to result in a net deposition of material on the surface 28, thereby forming a top portion 43 of the second layer 24b that covers a top portion 45 of first layer 24a. However, the neutral species are at least partially shielded from the surface 29 of the bottom wall 22 by the depth of the feature 16, and thus a net removal of material by the energetic sputtered ions occurs at the bottom wall 22. A net deposition of material on the sidewalls 20 of the features 16 results due to a combination of deposition of neutral species on the sidewalls and backsputtering of the ionized species from the surface 35 of the bottom wall, thereby forming side portions 39 of the second layer 24b that cover the feature sidewalls 20 and underlying side portions 41 of the first layer 24a. The second sputtering stage may be performed until the bottom portion 15 of the first layer 24a and the bottom portion 30 of the barrier layer 18 have been at least partially removed to expose a surface 26 of the underlying conducting layer 14, and even until a predetermined depth of the conducting material layer 14 has been sputtered away.

In one version, the process conditions selected in the second sputter deposition stage comprise a second bias power level applied to the support 130 that is higher than the first bias power level applied during the first stage. The second higher bias power level allows for an increased number of energetic ionized sputtered material. The second higher bias power level may be for example at least about 1.5 times higher than the first bias power level, such as from about 1.5 to about 4 times higher. A suitable second bias power level may be, for example, at least about 200 Watts, and even at least about 225 Watts, for example from about 225 Watts to about 800 Watts. The process conditions selected during the second process stage may also comprise maintaining a second pressure of sputtering gas in the chamber 106 that is lower than the first pressure during the first sputter deposition stage. The lower pressure allows for a greater number of energized sputtered ions. The second lower pressure may be, for example, at least about 2 times lower than the first pressure, such as from about 2 to about 5 times lower. A suitable second pressure may be, for example, from about 0 mTorr to about 2 mTorr, and even from about 0 mTorr to about 1.5 mTorr.

A third stage may be performed to sputter deposit a third layer 24c of sputtered material over the sidewalls 20 and bottom wall 22 of the feature 16. In one version, the third stage may be performed to deposit the third layer 24c over the first and second layers 24a,b on the sidewalls 20 of the feature 16 and top surface 28 of the substrate as well as over the exposed surface 26 of the underlying conducting layer 14, as shown in FIG. 4c. The process conditions are selected in the third sputter deposition stage to provide fewer highly energized ions of sputtered material, thereby decreasing the energetic bombardment of the substrate 10 and increasing the deposition of the material on the surfaces 35 of the substrate 10. The third sputter deposition stage forms a conformal third layer 24c that covers the sidewalls 20 of the feature 16 and covers the expose surface 26 of the underlying conducting layer 14 to form a connecting interface between the upper layers 24a,b,c and the underlying layer 14.

The process conditions selected in the third process stage comprise a third bias power level applied to the support 130 that is lower than the second bias power level provided during the second sputter deposition stage. In one version, the third bias power level may even be greater than the first bias power level applied to the support 130 during the first stage, as the danger posed by sputtering material from the barrier layer sidewalls 33 onto the bottom of the feature 16 is reduced in the third stage. A suitable third bias power level may be less than about 200 Watts, such as for example from about 0 Watts to about 200 Watts, and may even be less than about 150 Watts, such as for example from about 0 Watts to about 150 Watts. The process conditions selected during the third process stage may further comprise maintaining a third pressure of process gas in the chamber 106 that is greater than the second pressure maintained in the second process stage, to provide less energized ionic species. A suitable third pressure of sputtering gas maintained during the third stage comprises a third pressure of at least about 3 mTorr, for example from about 3 mTorr to about 10 mTorr, and even from about 4 mTorr to about 10 mTorr.

The multistage deposition process described above provides a significant improvement in the deposition of material in features 16 on a substrate 10. This is because by depositing the first layer 24a of material on the sidewalls 20 of the feature 16, the sidewall portions 33 of the barrier layer 18 are protected and any sputtering of material from the barrier layer sidewall portions in the second stage is inhibited by the overlying first layer 24a. While partial sputtering of the sloped sidewalls 20 may occur during the second stage, the material sputtered from the sidewalls 20 is substantially absent any barrier layer material, and thus may be allowed to re-deposit in the bottom of the feature 16 substantially without undesirably increasing the resistance of the final interconnect structure. This is a great improvement over methods in which an unprotected barrier layer is exposed to sputtering by high energy ionized species, resulting in the re-deposition of the barrier layer material in the bottom of the feature 16 and an undesirable increase in the resistance of the interconnect. The invention furthermore provides an unexpected advantage, as it was not expected that a sputter deposition process performed with the intention of removing a portion of a barrier layer 18 could be improved by first depositing an extra layer of material on top of the barrier layer before removing the portion of the barrier layer 18.

Thus, the above-described process provides an improved method for the deposition of sputtering material in a feature 16 comprising with sloped walls by reducing the incidence of sputtering of barrier layer material into the bottom of the feature 16. Once the sputtering process is finished, the upper surface 28 of the substrate 10 may be cleaned or otherwise polished to remove the layers 24a,b,c deposited on the upper surface 28. The remaining layers 24a,b,c coating the feature sidewalls 20 and bottom wall 22 may serve as seed layers in an electroplating process, to fill the feature with electroplated material.

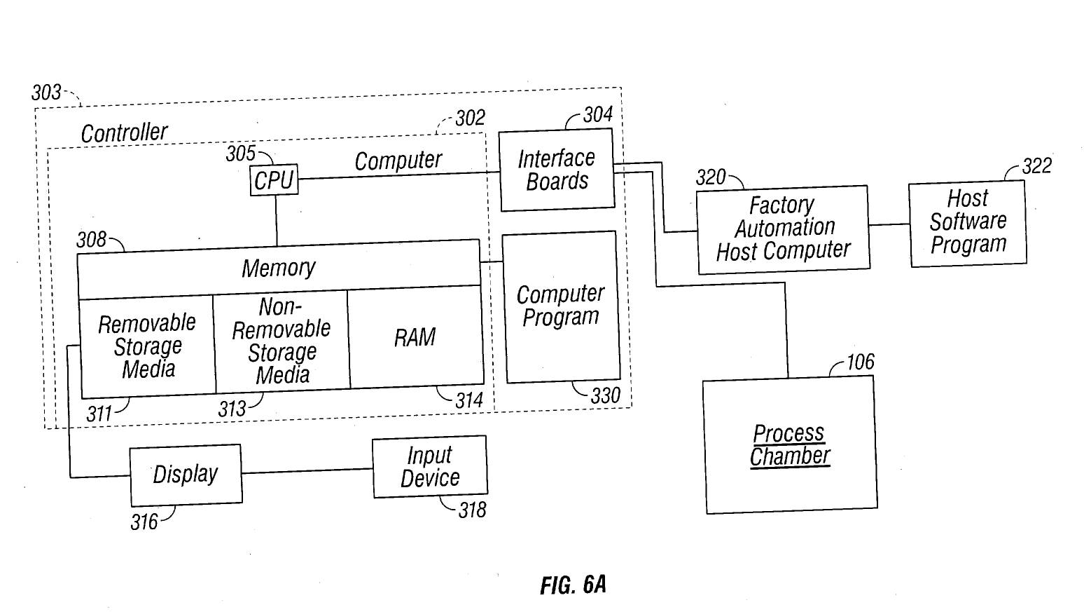

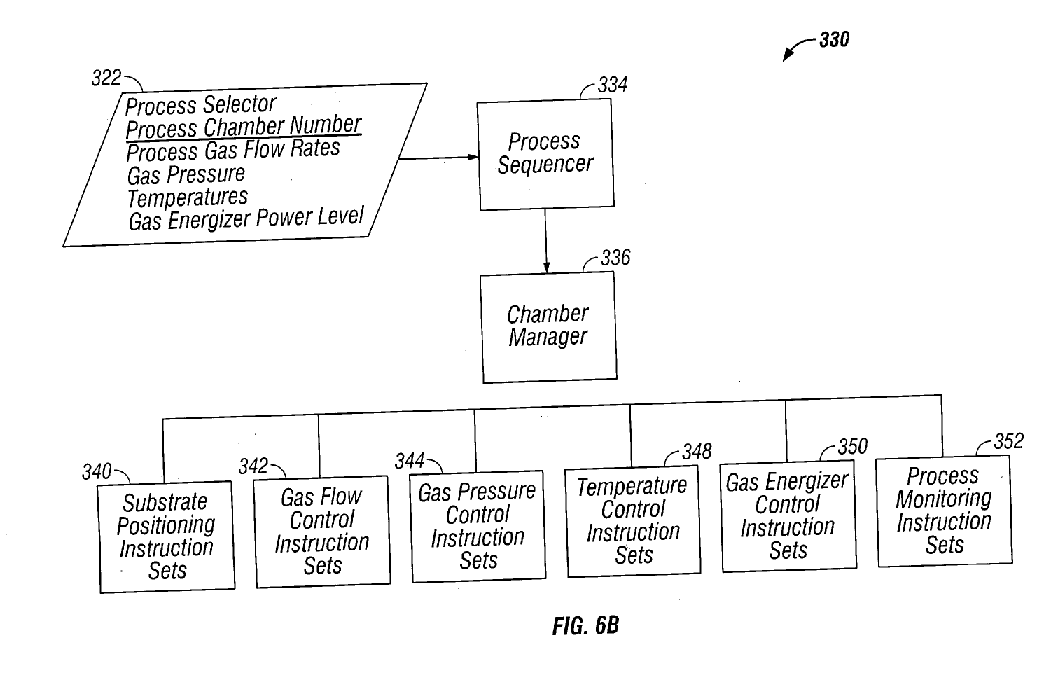

The chamber 106 may be operated by a controller 303 comprising a computer 302 that sends instructions via a hardware interface 304 to operate the chamber components, including the substrate support 130 to raise and lower the substrate support 130, the gas flow control valves 158a-c, the gas energizer 180, and the throttle valve 174, as shown for example in FIGS. 3a and 6a. The process conditions and parameters measured by the different detectors in the chamber 106, or sent as feedback signals by control devices such as the gas flow control valves 158a-c, pressure monitor (not shown), throttle valve 174, and other such devices, are transmitted as electrical signals to the controller 303. Although, the controller 303 is illustrated by way of an exemplary single controller device to simplify the description of present invention, it should be understood that the controller 303 may be a plurality of controller devices that may be connected to one another or a plurality of controller devices that may be connected to different components of the chamber 106 B thus, the present invention should not be limited to the illustrative and exemplary embodiments described herein.

The controller 303 comprises electronic hardware including electrical circuitry comprising integrated circuits that is suitable for operating the chamber 106 and its peripheral components, as shown in FIG. 6a. Generally, the controller 303 is adapted to accept data input, run algorithms, produce useful output signals, detect data signals from the detectors and other chamber components, and to monitor or control the process conditions in the chamber 106. For example, the controller 303 may comprise a computer 302 comprising (i) a central processing unit (CPU) 305, such as for example a conventional microprocessor from INTEL corporation, that is coupled to a memory 308 that includes a removable storage medium 311, such as for example a CD or floppy drive, a non-removable storage medium 313, such as for example a hard drive or ROM, and RAM 314; (ii) application specific integrated circuits (ASICs) that are designed and preprogrammed for particular tasks, such as retrieval of data and other information from the chamber 106, or operation of particular chamber components; and (iii) interface boards 304 that are used in specific signal processing tasks, comprising, for example, analog and digital input and output boards, communication interface boards, and motor controller boards. The controller interface boards 304, may for example, process a signal from a process monitor 210 and provide a data signal to the CPU 305. The computer 302 also has support circuitry that include for example, co-processors, clock circuits, cache, power supplies and other well known components that are in communication with the CPU 305. The RAM 314 can be used to store the software implementation of the present invention during process implementation. The instruction sets of code of the present invention are typically stored in storage mediums 311, 313 and are recalled for temporary storage in RAM 314 when being executed by the CPU 305. The user interface between an operator and the controller 303 can be, for example, via a display 316 and a data input device 318, such as a keyboard or light pen. To select a particular screen or function, the operator enters the selection using the data input device 318 and can reviews the selection on the display 316.

The data signals received and evaluated by the controller 303 may be sent to a factory automation host computer 320. The factory automation host computer 320 may comprise a host software program 322 that evaluates data from several systems, platforms or chambers 106, and for batches of substrates 10 or over an extended period of time, to identify statistical process control parameters of (i) the processes conducted on the substrates, (ii) a property that may vary in a statistical relationship across a single substrate, or (iii) a property that may vary in a statistical relationship across a batch of substrates. The host software program 322 may also use the data for ongoing in-situ process evaluations or for the control of other process parameters. A suitable host software program comprises a WORKSTREAM software program available from aforementioned Applied Materials. The factory automation host computer 320 may be further adapted to provide instruction signals to (i) remove particular substrates 10 from the etching sequence, for example, if a substrate property is inadequate or does not fall within a statistically determined range of values, or if a process parameter deviates from an acceptable range; (ii) end processing in a particular chamber 106, or (iii) adjust process conditions upon a determination of an unsuitable property of the substrate 10 or process parameter. The factory automation host computer 320 may also provide the instruction signal at the beginning or end of etching of the substrate 10 in response to evaluation of the data by the host software program 322.

In one version, the controller 303 comprises a computer program 330 that is readable by the computer 302 and may be stored in the memory 308, for example on the non-removable storage medium 313 or on the removable storage medium 311, as shown in FIG. 6b. The computer program 330 generally comprises process control software comprising program code to operate the chamber 106 and its components, process monitoring software to monitor the processes being performed in the chamber 106, safety systems software, and other control software. The computer program 330 may be written in any conventional programming language, such as for example, assembly language, C++, Pascal, or Fortran. Suitable program code is entered into a single file, or multiple files, using a conventional text editor and stored or embodied in computer-usable medium of the memory 308. If the entered code text is in a high level language, the code is compiled, and the resultant compiler code is then linked with an object code of pre-compiled library routines. To execute the linked, compiled object code, the user invokes the object code, causing the CPU 305 to read and execute the code to perform the tasks identified in the program.

An illustrative block diagram of a hierarchical control structure of a specific embodiment of a computer program 330 according to the present invention is shown in FIG. 6b. Using the data input device 318, for example, a user enters a process set and chamber number into the computer program 330 in response to menus or screens on the display 316 that are generated by a process selector 332. The computer program 330 includes instruction sets to control the substrate position, gas flow, gas pressure, temperature, power levels, and other parameters of a particular process, as well as instructions sets to monitor the chamber process. The process sets are predetermined groups of process parameters necessary to carry out specified processes. The process parameters are process conditions, including without limitations, gas composition, gas flow rates, temperature, pressure, and gas energizer settings such as RF or microwave power levels and magnetic field strengths. The chamber number reflects the identity of a particular chamber when there are a set of interconnected chambers on a platform.

A process sequencer 334 comprises instruction sets to accept a chamber number and set of process parameters from the computer program 330 or the process selector 332 and to control its operation. The process sequencer 334 initiates execution of the process set by passing the particular process parameters to a chamber manager 336 that controls multiple tasks in a chamber 106. The chamber manager 336 may include instruction sets, such as for example, substrate positioning instruction sets 340, gas flow control instruction sets 342, gas pressure control instruction set 344, temperature control instruction sets 348, gas energizer control instruction sets 350, and process monitoring instruction sets 352. The substrate positioning instruction set 340 comprises code for controlling chamber components that are used to load a substrate 10 onto the substrate support 130, and optionally, to lift a substrate 10 to a desired height in the chamber 106. The temperature control instruction sets 348 may comprise, for example, code for controlling the temperature of the substrate 10 during processing or code for controlling the temperature of walls of the chamber 106, such as the temperature of the ceiling. The process monitoring instruction sets 352 may comprise program code to monitor a process in the chamber 106. The gas flow control instruction sets 342 comprises code for controlling the flow rates of different constituents of the process gas. For example, the gas flow control instruction sets 342 may regulate the opening size of the gas flow control valves 158a-c to obtain the desired gas flow rates from the gas outlets 164a,b into the chamber 106.

The gas pressure control instruction sets 344 comprise program code for controlling the pressure in the chamber 106 by regulating open/close position of the throttle valve 174. For example, the gas pressure control instruction sets 344 may comprise code to set a first pressure of sputtering gas in the chamber during a first sputter deposition stage to deposit the first layer 24a of sputtered material on the substrate 10, and may comprise code to set a second pressure of the sputtering gas during a second sputter deposition stage that is lower than the first pressure to deposit the second layer 24b of sputtered material. The gas pressure control instruction sets 344 may also comprise code to set a third sputtering gas pressure during a third sputter deposition stage that is higher than the second pressure to deposit the third layer 24c of sputtered material.

The gas energizer control instruction sets 350 comprise code for controlling the gas energizer 180 to set the power level levels applied to the target 111, shield 128 and support 130 to energize the sputtering gas to sputter material from the target 111. The gas energizer control instruction sets 350 may also comprise code for controlling the magnetron 300 to set the magnetic field strength and the distribution of the magnetic field generated in the chamber 106. For example, the gas energizer control instruction sets 350 may comprise code to set a first bias power level applied to the support 130 during a first sputter deposition stage to deposit the first layer 24a of sputtered material on the substrate 10, and may comprise code to set a second bias power level applied to the support 130 during a second sputter deposition stage that is higher than the first bias power level to deposit the second layer 24b of sputtered material. The gas energizer control instruction sets 350 may also comprise code to set a third power level applied to the support 130 during a third sputter deposition stage that is lower than the second power level to deposit the third layer 24c of sputtered material.

While described as separate instruction sets for performing a set of tasks, it should be understood that each of these instruction sets can be integrated with one another, or the tasks of one set of program code integrated with the tasks of another to perform the desired set of tasks. Thus, the controller 303 and the computer program 330 described herein should not be limited to the specific version of the functional routines described herein; and any other set of routines or merged program code that perform equivalent sets of functions are also in the scope of the present invention. Also, while the controller is illustrated with respect to one version of the chamber 106, it may be used for any chamber described herein.

### EXAMPLE

The following example illustrates an exemplary method according to the present invention. While the example demonstrates one version, the present invention may be used in other processes and for other uses as would be apparent to those of ordinary skill in the art and the invention should not be limited to the example provided herein.

In this example, a substrate 10 was etched in the SIP+ chamber described above. The substrate 10 comprised a layer of silicon oxide 12 overlying a layer of copper 14, the overlying silicon oxide layer 12 having features 16 formed therein to expose a surface 26 of the underlying copper layer 14. A barrier layer 18 of tantalum nitride was deposited over the sidewalls 20 of the feature 16 to protect the silicon oxide layer 12 and also over the bottom wall 22 of the feature 16, thereby covering the surface 26 of the underlying copper layer 14. A multistage sputter deposition process was then performed to deposit layers of copper 24a,b,c.in the feature 16. Table 1 illustrates process parameters used in the deposition stages.

TABLE 1

| | Support Bias Power Level | Chamber Pressure |
|---|---|---|
| | (Watts) | (mTorr) |
| First Deposition Step | 0 | 4.8 |
| Second Deposition Step | 225 | 1.5 |
| Third Deposition Step | 150 | 4.8 |

In the first sputter deposition stage, a first layer 24a of copper was sputter deposited on the sidewalls 20 and bottom wall 22 of the feature 16 to protect the feature sidewalls 20. The first deposition stage was performed by introducing a sputtering gas comprising Ar into the chamber 106 at a gas flow rate equivalent to 90 sccm. The sputtering gas was energized to sputter copper from the target 111 and onto the substrate 10 by applying a bias power level to the target 111 of 35 kilowatts while a magnetic field strength of 300 Gauss was maintained in the vicinity of the target 111. The pressure of the sputtering gas in the chamber 106 was maintained at 4.8 mTorr. A bias power level was not applied to the support 130. The first deposition stage was performed to deposit the first copper layer 24a on the substrate 10 until a first layer 24a having a thickness of about 200 Å A was obtained.

In the second sputter deposition stage, a second layer 24b of copper was sputter deposited on the sidewalls 20 of the feature 16, and bottom portions 15,30 of the first copper layer 24a and barrier layer 18 were sputtered away to remove the bottom portions 15,30. The second deposition stage was performed by introducing a sputtering gas comprising Ar into the chamber 106 at a gas flow rate equivalent to 22 sccm. The sputtering gas was energized to sputter copper from the target 111 and onto the substrate 10 by applying a bias power level to the target 111 of 40 kiloWatts and a bias power level to the support 130 of 225 Watts while a magnetic field strength of 300 Gauss was maintained in the vicinity of the target 111. The pressure of the sputtering gas in the chamber 106 was maintained at 1.5 mTorr. The second deposition stage was performed until the bottom portions 15, 30 of the first copper layer 24 and barrier layer 18 had been sufficiently removed to expose the surface 26 of the underlying copper layer 14, and to provide a thickness of the second copper layer 24b on the sidewalls 20 of the feature 16 of at least 40 Å.

In the third sputter deposition stage, a third layer 24c of copper was sputter deposited on the sidewalls 20 and bottom wall 22 of the feature 16 over the first and second copper layers 24a,b and over the exposed surface 26 of the underlying copper layer 14. The third deposition stage was performed by introducing a sputtering gas comprising Ar into the chamber 106 at a gas flow rate equivalent to 90 sccm. The sputtering gas was energized to sputter copper from the target 111 and onto the substrate 10 by applying a bias power level to the target 111 of 35 kiloWatts and a bias power level to the support 130 of 150 Watts while a magnetic field strength of 300 Gauss was maintained in the vicinity of the target 111. The pressure of the sputtering gas in the chamber 106 was maintained at 4.8 mTorr. The third deposition stage was performed to until a third copper layer 24c having a thickness of 150 Å was obtained.

The present invention has been described in considerable detail with reference to certain preferred versions thereof. However, other versions are possible. For example, the present invention can be used to deposit many different materials on the substrate, and is not limited to processing of semiconductor substrates. Therefore the spirit and scope of the appended claims should not be limited to the description of the preferred versions contained herein.

What is claimed is:

1. A sputter deposition method performed in a sputtering chamber comprising a sputtering target facing a substrate support, the method comprising:
(a) placing a substrate on the support in the chamber;
(b) in a first sputtering stage, depositing a first layer of sputtered material on the substrate by:
(i) maintaining a first pressure of a sputtering gas in the chamber, and
(ii) maintaining the substrate support at a first bias power level; and
(c) in a second sputtering stage, depositing a second layer of sputtered material on the substrate by:
(i) maintaining a second pressure of the sputtering gas is that is lower than the first pressure, and
(ii) maintaining the substrate support at a second bias power level that is higher than the first bias power level.

2. A method according to claim 1 wherein the first pressure is at least about 3 mTorr and the-second pressure is less than about 2 mTorr

3. A method according to claim 1 wherein the first support bias power level is less than about 200 Watts and the second support bias power level is at least about 200 Watts.

4. A method according to claim 1 wherein the sputtered material comprises at least one of copper, aluminum, tantalum and titanium.

5. A method according to claim 1 further comprising:
(d) in a third sputtering stage, maintaining a third pressure of the sputtering gas of from about 3 mTorr to about 10 mTorr and maintaining a third bias power level of from about 0 Watts to about 200 Watts.

6. A sputter deposition method performed in a sputtering chamber comprising a sputtering target facing a substrate support, the method comprising:
(a) placing a substrate on the support in the chamber, the substrate comprising a first layer overlying a second layer, the first layer comprising a feature having a bottom wall and sloped sidewalls;
(b) in a first sputtering stage, maintaining first sputtering process conditions to deposit sputtered material on the sloped sidewalls of the feature, thereby protecting the sloped sidewalls, the first sputtering process conditions comprising:
(i) maintaining a pressure of a sputtering gas in the chamber of from about 3 mTorr to about 10 mTorr, and
(ii) maintaining the substrate support at a first bias power level of from about 0 Watts to about 200 Watts; and
(c) in a second sputtering stage, maintaining second sputtering process conditions to sputter the bottom wall of the feature to expose a portion of the second layer, the second sputtering process conditions comprising:
(i) maintaining a pressure of the sputtering gas in the chamber of from about 0 mTorr to about 2 mTorr; and
(ii) maintaining the substrate support at a second bias power level that is higher than the first bias power level, the second bias power level being from about 200 Watts to about 800 Watts.

7. A method according to claim 6 further comprising:
in a third sputtering stage, maintaining third sputtering process conditions to deposit sputtered material on the exposed portion of the second layer, the third sputtering process conditions comprising maintaining a pressure of the sputtering gas in the chamber of from about 3 mTorr to about 10 mTorr, and maintaining the substrate support at a bias power level of from about 0 Watts to about 200 Watts.

8. A sputter deposition method performed in a sputtering chamber comprising a sputtering target comprising copper facing a substrate support, the method comprising:
(a) placing a substrate on the support in the chamber, the substrate comprising a barrier layer over an underlying layer of copper, wherein the barrier layer comprises a feature formed therein, the feature having a bottom wall and sloped sidewalls;
(b) in a first sputtering stage, maintaining first sputtering process conditions to deposit copper sputtered from the target onto the sloped sidewalls of the feature, thereby protecting the sloped sidewalls, the first sputtering process conditions comprising:
(i) maintaining a pressure of a sputtering gas comprising Ar in the chamber of from about 3 mTorr to about 10 mTorr, and
(ii) maintaining the substrate support at a first bias power level of from about 0 Watts to about 200 Watts; and
(c) in a second sputtering stage, maintaining second sputtering process conditions to sputter the bottom wall of the feature to expose a portion of the underlying copper layer, the second sputtering process conditions comprising;
(i) maintaining a pressure of the sputtering gas in the chamber of from about 0 mTorr to about 2 mTorr; and
(ii) maintaining the substrate support at a second bias power level that is higher than the first bias power level, the second bias power level being from about 200 Watts to about 800 Watts; and
(d) in a third sputtering stage, maintaining third sputtering process conditions to deposit copper sputtered from the target onto the sidewalls of the feature and onto the exposed portion of the underlying copper layer, the third sputtering process conditions comprising:
(i) maintaining a pressure of the sputtering gas in the chamber of from about 3 mTorr to about 10 mTorr; and
(ii) maintaining the substrate support at a third bias power that is less than the second bias power level, the third bias power level being from about 0 Watts to about 200 Watts.

9. A sputtering chamber for sputter depositing material on a substrate, the chamber comprising:
a substrate support;
a target facing the substrate support;
a sputtering gas delivery system to provide a sputtering gas in the chamber;
a gas energizer to energize the sputtering gas by applying bias power levels to the target and the substrate support, thereby sputtering material from the target onto the substrate;
an exhaust comprising a throttle valve to control a pressure of the sputtering gas in the chamber; and
a controller comprising a computer having computer readable program code embodied in a computer readable medium, the computer readable program code comprising:
(i) gas energizer control instruction sets to operate the gas energizer to:
(1) during a first sputtering stage, apply a first bias power level to the support; and
(2) during a second sputtering stage performed after the first sputtering stage, apply a second bias power level to the support that is higher than the first bias power level; and
(ii) gas pressure control instruction sets to operate the throttle valve to:
(1) during the first sputtering stage, maintain a first pressure of sputtering gas in the chamber; and
(2) during the second sputtering stage, maintain a second pressure of the sputtering gas that is lower than the first pressure.

10. An apparatus according to claim 9 wherein the gas pressure control instruction sets operate the throttle valve to provide a first pressure of from about 0 mTorr to about 2 mTorr, and a second pressure of from about 3 mTorr to about 10 mTorr.

11. A method according to claim 9 wherein the gas energizer control instruction sets operate the gas energizer to apply a first bias power level to the support of from about 0 Watts to about 200 Watts, and a second bias power level to the support of from about 200 Watts to about 800 Watts.

12. A method according to claim 9 wherein the gas pressure control instruction sets operate the throttle valve to provide a third pressure of the sputtering gas in the chamber of from about 3 mTorr to about 10 mTorr in a third sputtering stage performed after the second sputtering stage, and wherein the gas energizer control instruction sets operate the gas energizer to apply a third bias power level to the support during the third sputtering stage that is lower than the second bias power level, the third bias power level being from about 0 Watts to about 200 Watts.
